(19) United States
(12) Patent Application Publication
(10) Pub. No.: US 2009/0230421 A1
(43) Pub. Date: Sep. 17, 2009

(54) Semiconductor package structure, lead frame and conductive assembly for the same

(76) Inventor: Cheng-Hong Su, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/213,217

(22) Filed: Jun. 17, 2008

(30) Foreign Application Priority Data
Mar. 14, 2008 (CN) 200810085425.1

(51) Int. Cl. H01L 33/00; H01L 23/495

(52) U.S. Cl. 257/99; 257/676; 257/E33.001; 257/E23.031

(57) ABSTRACT

A light emitting diode package structure, and a lead frame and a conductive assembly for the same are described. The light emitting diode package structure includes a conductive assembly, a semiconductor chip, and a package body. The conductive assembly includes a chip support and a bonding support. The chip support has a carrier surface, and the bonding support has at least one wiring portion surrounding the carrier surface. The semiconductor chip is disposed on the carrier surface and electrically connected to the wiring portion through a wire. The n, the package is used to encapsulate the semiconductor chip, the wire, the carrier surface, and the wiring portion so as to form a light emitting diode package structure.

### CROSS-REFERENCE TO RELATED APPLICATIONS

This non-provisional application claims priority under 35 U.S.C. §119(a) on Patent Application No(s). 200810085425.1 filed in China, P.R.C. on Mar. 14, 2008 the entire contents of which are hereby incorporated by reference.

### BACKGROUND OF THE INVENTION

1. Field of Invention

The present invention relates to a light emitting diode package structure, in particular, to a light emitting diode package structure, and a lead frame and a conductive assembly for the same.

2. Related Art

With the continuous progress in photoelectric technology, the light-emitting diode (LED) technique is becoming mature. Due to the advantages of long service life, power-saving, and small size, LEDs has gradually replaced the conventional incandescent lamp for illumination or warning purpose.

In recent years, high-performance LEDs have been developed to satisfy the users' demands for higher efficiency, and Piranha type LED is the most outstanding one. Compared with the conventional LED, the Piranha type LED provides higher luminance and wider illumination angles. Further, the Piranha type LED has four electrical pins, which are contributive to thermal dissipation and steadily supporting the LED.

FIGS. 1A and 1B are schematic views of a conductive assembly and a lead frame for a conventional Piranha type LED.

Referring to FIG. 1A, the conductive assembly 10 of a conventional Piranha type LED includes a chip support 11 and a bonding support 12. The chip support 11 has a carrier surface 13 for carrying a light-emitting chip 14 thereon. The light-emitting chip 14 is electrically connected to the bonding support 12 through a wire 15, so as to form a chip bonding area with the carrier surface 13 as its center. Afterwards, a package body 16 made of epoxy resin, silica gel, and phosphor powder is used to encapsulate the chip bonding area to form a complete Piranha type LED.

Referring to FIG. 1B, a common lead frame 20 with a pin spacing of 12.7 mm is taken as an example. Electrical pins 17 extending from two sides of each half-finished conductive assembly are respectively connected by two operating bars 21, and thus the half-finished conductive assemblies are serially-connected. During the manufacturing of the conductive assemblies, the operating bars are clamped by conveyor machines to go through the stamping and electroplating processes, so as to achieve the purpose of automatic production. Finally, after the packaging of the conductive assembly, the operating bars are removed to form a single finished product of the Piranha type LED.

In the package structure of the conventional Piranha type LED, the chip bonding area is limited to the periphery of the carrier surface of the chip support, and the light-emitting chip relies only on a single bonding area formed by electrically connecting the wire and the bonding support. Thus, during the packaging process, the stress variation and thermal expansion and cold shrinkage of the package body focus on the juncture of the package body and the conductive assembly. Moreover, the package body made of a resin material has a thermal expansion coefficient different from that of the conductive assembly made of a metal material, so the wire may be easily broken under the effect of the stress (dragging force) inside the package structure, resulting in that the Piranha type LED cannot emit lights.

The price of metal materials is continuously rising currently, for example, the price of copper and iron used in the Piranha type LED is increased by about 110%-200%. The operation bars which are eventually discarded as waste materials and increased amount of electroplating silver used in the electroplating process of an over-sized lead frame will greatly increase the material cost of the Piranha type LED. Thus, the manufacturers have to raise the product price to balance the cost. Otherwise, the manufacturers have to lower the profit to stimulate the sales.

Therefore, it is a problem in urgent need of solutions to prevent the breaking of the wire under different stresses caused in the packaging process and effectively utilize the space of the lead frame, so as to further reduce the volume of the operating bars to be removed. Thus, the manufacturer may improve the quality of the Piranha type LED, and also reduce the manufacturing cost.

### SUMMARY OF THE INVENTION

In view of the above problem, the present invention provides a light emitting diode package structure, and a lead frame and a conductive assembly for the same, so as to solve the problem that the product reliability is impaired due to the breaking of the wire under different stresses in the conventional Piranha type LED.

The light emitting diode package structure of the present invention includes a conductive assembly, a semiconductor chip, and a package body. The conductive assembly further includes a chip support and a bonding support. The chip support has a carrier surface and at least one first electrical pad extending from the carrier surface. The bonding support has at least one wiring portion surrounding the carrier surface and interdigitated with the carrier surface, and at least one second electrical pad extending from the wiring portion. The semiconductor chip is disposed on the carrier surface and electrically connected to the wiring portion through at least one wire. The package body encapsulates the semiconductor chip, the wire, the carrier surface, and the wiring portion to form the light emitting diode package structure.

In addition, the bonding support of the present invention also has an extending portion surrounding the carrier surface and interdigitated with the carrier surface, and is encapsulated by the package body, so as to provide the lead frame with several bonding areas to choose therefrom.

The advantage of the present invention lies in that, at least one wiring portion extends from the bonding support, so as to solve the problem that the wire may be easily broken due to the inner stress (dragging force) caused by different thermal expansion coefficients of the package body and the conductive assembly in the course of the packaging of the semiconductor, and thus the reliability of the light emitting diode package structure is improved.

### BRIEF DESCRIPTION OF THE DRAWINGS

The present invention will become more fully understood from the detailed description given herein below for illustration only, and thus are not limitative of the present invention, and wherein:

FIG. 1A is a perspective view of a conventional conductive assembly;

FIG. 1B is a schematic plan view of a conventional lead frame;

FIG. 2 is a schematic plan view of a lead frame of the present invention;

FIG. 3A is a perspective view of a conductive assembly of the present invention;

FIG. 3B is a perspective view of a conductive assembly of the present invention; and

FIG. 4 is a perspective view of a light emitting diode package structure of the present invention.

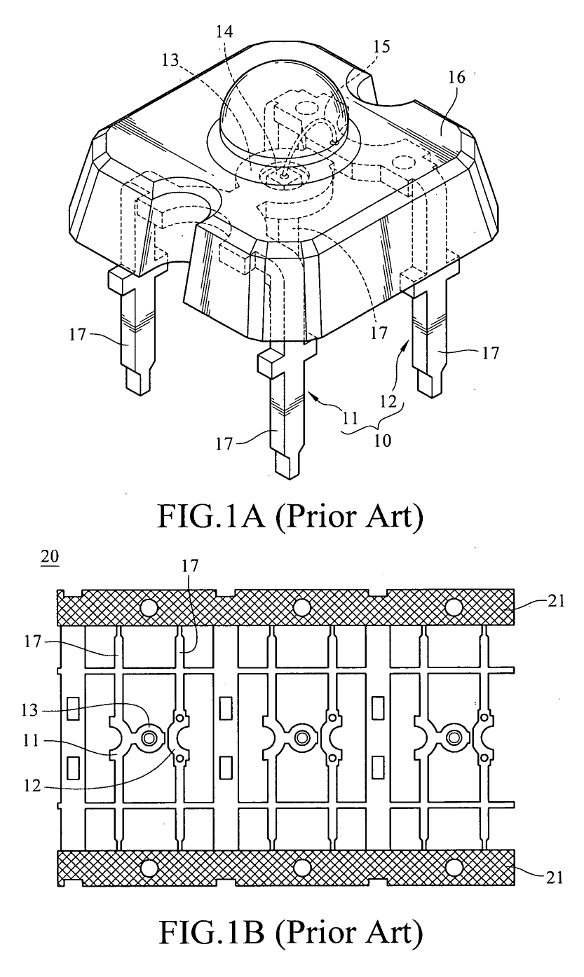

### DETAILED DESCRIPTION OF THE INVENTION

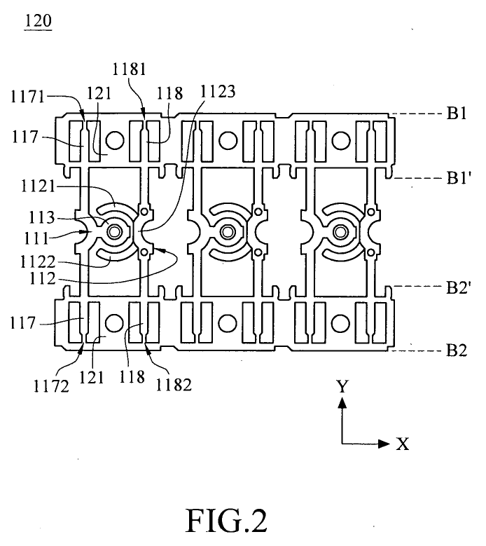

FIG. 2 is a schematic view of a lead frame for a light emitting diode package structure of the present invention. The lead frame 120 of the present invention includes a chip support 111, a bonding support 112, and two operating bars 121. The chip support 111 has a carrier surface 113, and two first electrical pads 117 respectively extending from the carrier surface 113 in Y and −Y directions. The bonding support 112 includes a central wiring portion 1123, and two second electrical pads 118 respectively extending from the central wiring portion 1123 in Y and −Y directions.

The lead frame 120 is designed to have two operating bars 121. The two operating bars 121 are respectively disposed on the upper and lower sides of the lead frame 120, and further connected to the two first electrical pads 117 and the two second electrical pads 118 respectively. Further, the two operating bars 121 function as a position control unit (medium) for conveying, i.e., operate like a chain conveyor, thus achieving the purpose of automatic production. As far as one side (in the Y direction) of the lead frame 120 is concerned, the first electrical pad 117 and the second electrical pad 118 respectively have a first end 1171 and a second end 1181, and the two ends 1171, 1181 are located within the operating bar 121. Further, the two ends 1171, 1181 are located between a first outer border B 1 and a first inner border B1′ of the operating bar 121.

Accordingly, the positions of the ends of the electrical pads 117, 118 may determine the positions of the inner/outer borders of the operating bar 121. Similarly, the first electrical pad 117 and the second electrical pad 118 on the other side (in the −Y direction) of the lead frame 120 may also have a first end 1172 and a second end 1182 respectively, and the two ends are located between a second outer border B2 and a second inner border B2′ of the operating bar 121 on this side.

As described above, without influencing the conveying and positioning function and automatic stamping and electroplating processes of the operating bars, the lead frame 120 architecture of the present invention not only enhances the structural strength of the lead frame 120, but also reduces the width of the conventional lead frame 120 from 25.4 mm to 20.4 mm. Thus, the total volume of the lead frame 120 is greatly reduced, thereby further reducing the amount of material used by the lead frame 120 and the material and manufacturing costs of the electroplating process.

In addition, the bonding support 112 further includes wiring portions 1121, 1122 surrounding the periphery of the carrier surface 113, so as to provide the lead frame 120 with several bonding areas to choose therefrom.

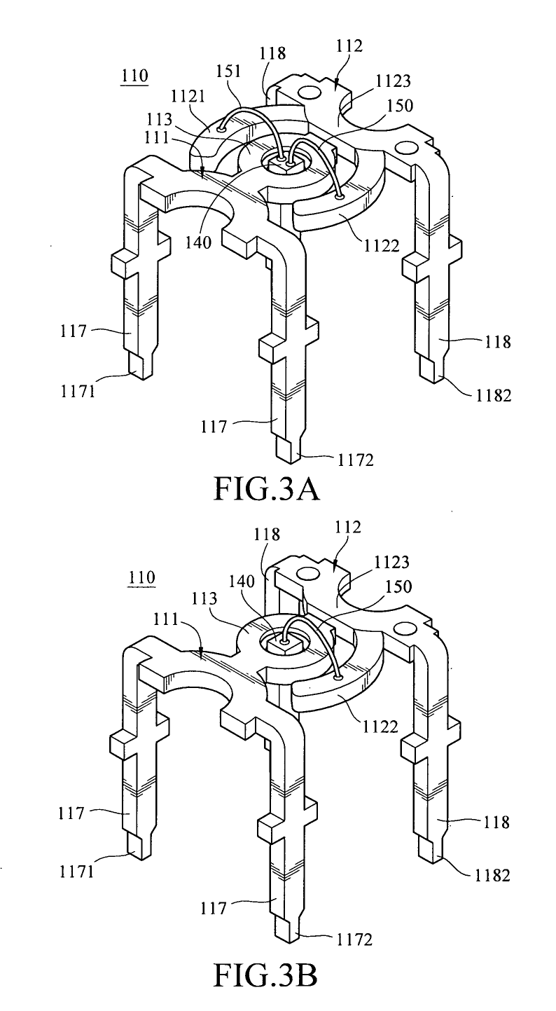

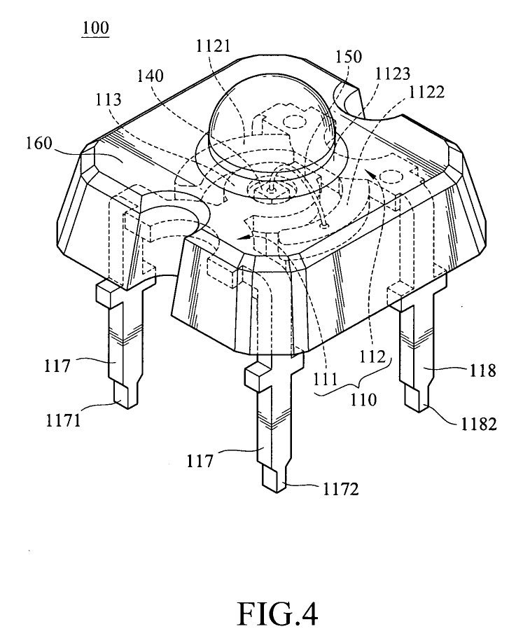

FIGS. 3A and 4 are perspective views of a light emitting diode package structure and a conductive assembly for the same according to the present invention. The light emitting diode package structure 100 of the present invention includes a conductive assembly 110, a semiconductor chip 140, and a package body 160. The light emitting diode package structure 100 of the present invention is an LED package structure.

The conductive assembly 110 of the present invention includes a chip support 111 and a bonding support 112. The chip support 111 has a carrier surface 113 and two first electrical pads 117 extending from the carrier surface 113. The bonding support 112 includes two wiring portions 1121, 1122 surrounding the periphery of the carrier surface 113, and a second electrical pad 118 extending from the two wiring portions 1121, 1122 respectively. A first wire 150 and a second wire 151 are respectively electrically connected to the semiconductor chip 140 and the wiring portions 1121, 1122. In the present invention, the chip support 111 and the bonding support 112 respectively has two electrical pads 117, 118. One of the electrical pads 117, 118 of the chip support 111 and the bonding support 112 respectively have a first end 1172 and a second end 1182, for electrically connecting an electrode (not shown) to provide an electric power to the conductive assembly 110. The other electrical pads 117, 118 of the chip support 111 and the bonding support 112 also respectively have a first end 1171 and a second end 1181, which are contributive to the thermal dissipation of the light emitting diode package structure 100, thus increasing the thermal dissipation area of the light emitting diode package structure 100.

Moreover, the two wiring portions 1121, 1122 and the carrier surface 113 form an interdigitated structure. In addition to providing multiple choices of bonding areas, a safe area free from the impact of the inner stress of the frame bending angle is also provided. Therefore, the problems of wire breaking or frame deformation caused by the inner stress in the subsequent process are avoided.

Further, besides the design of two wiring portions 1121, 1122 surrounding the carrier surface 113 in FIG. 3A, as shown in FIG. 3B, a single wiring portion 1122 surrounding the carrier surface 113 may also be adopted. A second electrical pad 118 electrically connected to the electrode extends from the wiring portion 1122. In addition, the first wire 150 is electrically connected to the semiconductor chip 140 and the wiring portion 1122.

The semiconductor chip 140 of the present invention is a light-emitting chip disposed on the carrier surface 113 of the chip support 111. Through the first wire 150 or the second wire 151 that electrically connects the semiconductor chip 140 to one second electrical pad 118 of the bonding support 112, in which the second electrical pad 118 is electrically connected to the electrode, the semiconductor chip 140 is electrically conducted to emit lights. It should be noted that according to the design of the semiconductor chip 140, the bonding support 112 of the present invention may further selectively electrically connect the two second electrical pads 118 to the electrode, such that the semiconductor chip 140 can be respectively connected to the two wiring portions 1121, 1122 of the bonding support 112 through the two wires 150, 151, thereby avoiding the breaking of a single wire and enhancing the reliability of the product.

However, the chip support 111 and the bonding support 112 of the conductive assembly 110 of the present invention may also be designed to respectively have a single electrical pad 117, 118. Further, a first end 1172 and a second end 1182 respectively extend from the electrical pads 117, 118 for electrically connecting an electrode, which is not limited to the embodiment of the present invention.

Further, referring to FIG. 4, the package body 160 is mainly made of epoxy resin or silicone coated with or mixed with phosphor powder, for encapsulating the carrier surface 113, at least one wiring portions 1121, 1122, the semiconductor chip 140, and the first wire 150 to form the light emitting diode package structure 100. The wiring portions 1121, 1122 of the bonding support 112 are disposed on the periphery of the carrier surface 113, so as to form a safe bonding area that endures least impacts of stress and deformation for the package body 160. Therefore, the stress impact caused by different thermal expansion coefficients of resin and metal materials between the bonding support 112 and the package body 160 can be effectively reduced, so as to avoid the breaking of the first wire 150 under the inner stress generated in the hardening of the package body 160.

In other words, the bonding support 112 and the chip support 111 of the light emitting diode package structure 100 are partially interdigitated. The interdigitated area is formed by any lateral extending portion of the bonding support 112 (for example, the wiring portions 1121, 1122 in the X direction) and the carrier surface 113. Therefore, the inner stress is not concentrated on semicircular notches at two ends of the package body 160 but on the interlaced area (the central area). As a result, the inner stress dragging outwardly generated during the hardening process of the package body 160 at the juncture between the package body 160 and the conductive assembly 110 is reduced accordingly.

Further, the first wire 150 is not located in a direction where the inner stress dragging outwardly is greater, but at a position perpendicular to the direction of the greatest stress.

In addition, the wiring portions 1121, 1122 of the present invention are designed to surround the carrier surface 113 of the chip support Ill according to the analysis result of Finite Element Analysis (FEA). The analysis simulation data is described as follows. The amount of deformation in the chip bonding area of the conventional Piranha type LED is between 0.0172 to 0.0315 mm, and the amount of deformation in the chip bonding area of the conductive assembly 110 of the present invention is between 0.0161 to 0.0295 mm which is apparently smaller than the conventional Piranha type LED. Therefore, the design of the wiring portion 1121 in the present invention can effectively solve the problem that the first wire 150 may be easily broken under the stress (dragging force) inside the light emitting diode package structure 100 caused by difference thermal expansion coefficients of the materials adopted by the package body 160 and the conductive assembly 110.

According to the light emitting diode package structure, and the lead frame and the conductive assembly for the same provided by the present invention, at least one wiring portion surrounding the carrier surface extends from the bonding support, so as to reduce the probability of breaking of the wire under the stress (dragging force) during the packaging, thereby enhancing the reliability of the light emitting diode package structure.

What is claimed is:

1. A light emitting diode package structure, comprising:
a conductive assembly, including a chip support and a bonding support, wherein the chip support has a carrier surface, and at least one wiring portion surrounding the carrier surface extends from the bonding support;
a semiconductor chip, disposed on the carrier surface, and electrically connected to the wiring portions through at least one wire; and
a package body, for encapsulating the semiconductor chip, the wire, the carrier surface, and the wiring portions.

2. The light emitting diode package structure according to claim 1, wherein two wiring portions surrounding the carrier surface extend from the bonding support.

3. The light emitting diode package structure according to claim 2, wherein the semiconductor chip is optionally electrically connected to one of the wiring portions through the wire.

4. The light emitting diode package structure according to claim 2, wherein the semiconductor chip is respectively electrically connected to the two wiring portions through two wires.

5. A light emitting diode package structure, comprising:
a conductive assembly, including a chip support and a bonding support, wherein the chip support has a carrier surface, and the bonding support has an extending portion interdigitated with the carrier surface;
a semiconductor chip, disposed on the carrier surface, and electrically connected to the bonding support; and
a package body, for encapsulating the semiconductor chip, the wire, the carrier surface, and the extending portion.

6. The light emitting diode package structure according to claim 5, wherein the semiconductor chip is electrically connected to the extending portion through a first wire.

7. The light emitting diode package structure according to claim 6, wherein the semiconductor chip is electrically connected to the extending portion through a second wire.

8. A conductive assembly for a light emitting diode package structure, comprising:
a chip support, including a carrier surface and at least one first electrical pad extending from the carrier surface; and
a bonding support, including at least one wiring portion surrounding the carrier surface, and at least one second electrical pad extending from the wiring portion.

9. The conductive assembly for a light emitting diode package structure according to claim 8, wherein the bonding support comprises two wiring portions surrounding the carrier surface.

10. A lead frame for a light emitting diode package structure, comprising:
a chip support, including a carrier surface and a first electrical pad extending from the carrier surface;
a bonding support, including a wiring portion and a second electrical pad extending from the wiring portion; and
an operating bar, respectively connected to the first electrical pad and the second electrical pad, wherein the operating bar has a first border and a second border, and the edges of the first and second electrical pads are located between the first border and the second border.

11. The lead frame for a light emitting diode package structure according to claim 10, wherein the bonding support has an extending portion surrounding the carrier surface.

12. The lead frame for a light emitting diode package structure according to claim 10, wherein the bonding support has two extending portions surrounding the carrier surface.

13. The lead frame for a light emitting diode package structure according to claim 10, wherein the bonding support and the chip support form an interdigitated structure.

14. The lead frame for a light emitting diode package structure according to claim 13, wherein the interdigitated structure is formed by the carrier surface and two extending portions extending from the wiring portion.

15. The lead frame for a light emitting diode package structure according to claim 10, wherein extending directions of the first electrical pad extending from the carrier surface and a second electrical pad extending from the wiring portion are the same.
